(19) United States
(12) Patent Application Publication
(10) Pub. No.: US 2025/0076906 A1
(43) Pub. Date: Mar. 6, 2025

(54) POWER CONTROL DEVICE FOR TEMPERATURE CONTROL, THERMAL PROCESSING SYSTEM HAVING THE SAME, AND TEMPERATURE CONTROL METHOD FOR THERMAL PROCESSING SYSTEM

(71) Applicant: AP SYSTEMS INC., Hwaseong-Si (KR)

(72) Inventors: Sang Hyun JI, Yongin-si (KR); Dae Ryong LEE, Hwaseong-si (KR); Yong Soo MOON, Seoul (KR)

(21) Appl. No.: 18/803,348

(22) Filed: Aug. 13, 2024

(30) Foreign Application Priority Data
Sep. 1, 2023 (KR) 10-2023-0116168

(51) Int. Cl. G05D 23/20; H01L 21/67

(52) U.S. Cl. CPC G05D 23/20; H01L 21/67115; H01L 21/67248

(57) ABSTRACT

The present disclosure relates to a power control device for temperature control capable of phase control compensation according to power fluctuations, a thermal processing system having the same, and a temperature control method for the thermal processing system. The power control device for temperature control includes a power control unit configured to control an amount of power supplied to a heating source by controlling a phase of AC power supplied from a power source and a power measurement unit connected to the power source and configured to measure the AC power, wherein the power control unit controls the phase of the AC power by compensating a phase angle according to a difference between a reference power value and the measured value measured by the power measurement unit.

### CROSS-REFERENCE TO RELATED APPLICATION

This application claims priority to Korean Patent Application No. 10-2023-0116168 filed on Sep. 1, 2023 and all the benefits accruing therefrom under 35 U.S.C. § 119, the contents of which are incorporated by reference in their entirety.

### BACKGROUND

The present disclosure relates to a power control device for temperature control, a thermal processing system having the same, and a temperature control method for the thermal processing system, and more particularly, to a power control device for temperature control capable of phase control compensation according to power fluctuations, a thermal processing system having the same, and a temperature control method for the thermal processing system.

Thermal processing is a process of annealing a substrate (e.g., a wafer) in substrate processing.

Such thermal processing may heat the substrate by turning on a plurality of lamps and irradiating the substrate with light, and cool the substrate by turning off the lamps. In this case, a temperature of the substrate may be measured and an amount of power supplied to each lamp may be controlled according to the temperature of the substrate so that the entire substrate is heated evenly, and the temperature of the substrate may be raised to 1,000° C. or more within a few seconds.

Here, power supplied to the lamp may be controlled using a thyristor such as a silicon controlled rectifier (SCR), and the power may be controlled by the thyristor by applying a phase angle control (PAC) method. For example, AC power may be input from a power source to the SCR, and when a gate current flows through a gate of the SCR, power may be output from the SCR and supplied to the lamp. Using this, in the PAC method, by changing the timing of the gate current applied to the SCR, a waveform of output power (e.g., output current waveform and output voltage waveform) may be changed, output power of the SCR (i.e., lamp input power) may be changed, and accordingly, an amount of power supplied to the lamp may be controlled.

Due to replacement of the power source of the thermal processing system or the occurrence of other unstable factors during use of the thermal processing system, fluctuations in AC power supplied from the power source to the SCR may occur. In this case, the amount of power supplied to the lamp may also fluctuates, which causes the output (intensity) of the lamp to differ from a set output, which may result in the substrate not being heated (or maintained) to a temperature close to (or similar to) a target temperature according to the measured temperature.

Therefore, temperature reproducibility that may suppress and/or prevent a difference between the output of the lamp and the set output and heats the substrate to a temperature close to the target temperature even if fluctuations in AC power supplied to the SCR from the power source occur.

### SUMMARY

The present disclosure provides a power control device for temperature control that may detect power fluctuations and perform phase control compensation according to the power fluctuations, a thermal processing system having the same, and a temperature control method for the thermal processing system.

In accordance with an exemplary embodiment, a power control device for temperature control includes: a power control unit configured to control an amount of power supplied to a heating source by controlling a phase of AC power supplied from a power source; and a power measurement unit connected to the power source and configured to measure the AC power, wherein the power control unit controls the phase of the AC power by compensating a phase angle according to a difference between a reference power value and the measured value measured by the power measurement unit.

The power control unit may include a phase calculation unit configured to calculate a control phase for the AC power from the reference power value according to an amount of applied power to the heating source and a phase angle compensation unit configured to calculate the phase angle from a difference value between the reference power value and the measured value measured by the power measurement unit and compensate the phase angle for the control phase calculated by the phase calculation unit.

The power control unit may further include a power amount setting unit configured to set the amount of applied power according to an output of the heating source.

The phase angle compensation unit may be configured to calculate the phase angle in proportion to the difference value between the reference power value and the measured value measured by the power measurement unit.

The phase angle compensation unit may be configured to add the phase angle to the control phase calculated by the phase calculation unit when the difference between the reference power value and the measured value measured by the power measurement unit is a positive number, and subtract the phase angle from the control phase calculated by the phase calculation unit when the difference between the reference power value and the measured value measured by the power measurement unit is a negative number.

The power source may be configured to supply three-phase AC power.

The power measurement unit may be configured to measure AC power of each phase, and the power control unit may be configured to respectively control a phase of the AC power of each phase by respectively compensating the phase angle according to the difference between the reference power value and the measured value measured by the power measurement unit, for the AC power of each phase.

In accordance with another exemplary embodiment, a thermal processing system includes the power control device for temperature control according to an embodiment of the present disclosure, a substrate support part provided opposite the heating source and configured to support a substrate, a temperature measurement unit configured to measure a temperature of the substrate, and a heating intensity calculation unit configured to calculate an output of the heating source according to the temperature of the substrate.

The heating source may include a plurality of lamps.

An amount of applied power to the heating source may be determined according to the output of the heating source calculated by the heating intensity calculation unit.

In accordance with yet another exemplary embodiment, a temperature control method for a thermal processing system includes measuring a temperature of a substrate supported on a substrate support part; calculating an output of a heating source that heats the substrate according to the measured temperature of the substrate; setting an amount of applied power to the heating source according to the calculated output of the heating source; and controlling an amount of power supplied to the heating source by controlling a phase of AC power supplied from a power source according to the set amount of applied power, wherein the controlling the amount of power supplied to the heating source includes a process of measuring the AC power, and a process of controlling a phase of the AC power by compensating a phase angle according to a difference between the measured value of the AC power and a reference power value.

The process of controlling the phase of the AC power may include a process of calculating a control phase for the AC power from the reference power value according to the set amount of applied power, a process of calculating the phase angle using a difference value between the reference power value and the measured value of the AC power, and a process of compensating the calculated phase angle for the calculated control phase.

In the process of calculating the phase angle, the phase angle may be calculated in proportion to the difference value between the measured value of the AC power and the reference power value.

The process of compensating the calculated phase angle may include a process of adding the calculated phase angle to the calculated control phase when a value obtained by subtracting the measured value of the AC power from the reference power value is a positive number and a process of subtracting the calculated phase angle from the calculated control phase when the value obtained by subtracting the measured value of the AC power from the reference power value is a negative number.

The power source may be configured to supply three-phase AC power and, in the process of controlling the phase of the AC power, a phase of the AC power of each phase may be respectively controlled by respectively compensating the phase angle according to the difference between the measured value of the AC power measured for the AC power of each phase and the reference power value.

### BRIEF DESCRIPTION OF THE DRAWINGS

Exemplary embodiments can be understood in more detail from the following description taken in conjunction with the accompanying drawings, in which:

FIG. 1 is a block diagram illustrating a power control device for temperature control in accordance with an exemplary embodiment;

FIG. 2 is a conceptual diagram for describing phase angle compensation in accordance with an exemplary embodiment;

FIG. 3 is a schematic cross-sectional view illustrating a thermal processing system in accordance with another exemplary embodiment; and

FIG. 4 is a flow chart illustrating a temperature control method for a thermal processing system in accordance with yet another exemplary embodiment.

### DETAILED DESCRIPTION OF EMBODIMENTS

Hereinafter, embodiments of the present disclosure will be described in more detail with reference to the attached drawings. However, the present disclosure is not limited to the embodiments disclosed below and will be implemented in various different forms. These embodiments are provided solely to ensure that the present disclosure is complete and to fully inform those skilled in the art of the scope of the invention. In the description, the same reference numerals are assigned to the same components, and the drawings may be partially exaggerated in size to accurately describe embodiments of the present disclosure. In the drawings, the same reference numerals refer to the same elements.

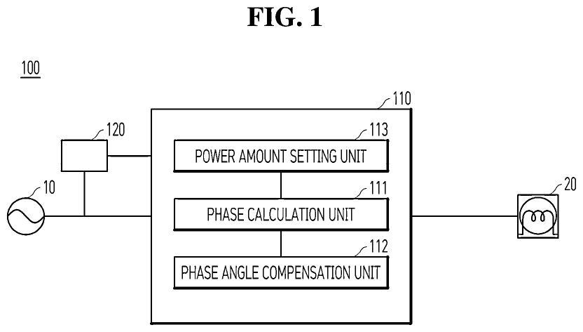

FIG. 1 is a block diagram illustrating a power control device for temperature control according to an embodiment of the present disclosure.

Referring to FIG. 1, a power control device 100 for temperature control according to an embodiment of the present disclosure may include a power control unit 110 that controls an amount of power supplied to a heating source 20 by controlling a phase of AC power supplied from a power source 10 and a power measurement unit 120 that is connected to the power source 10 and measures the AC power.

The power control unit 110 may control the amount of power supplied to the heating source 20 by controlling a phase of the AC power supplied from the power source 10, and control an amount of power supplied to the heating source 20 using a thyristor such as a silicon controlled rectifier (SCR) by applying a phase angle control (PAC) method. For example, the power control unit 110 may control the phase of the AC power by changing the timing of a gate current applied to a gate of the SCR into which the AC power is input, and adjust the amount of power supplied to the heating source 20 through such phase control. Here, power P may be a product of voltage V and current I, and the AC power may include AC voltage and AC.

The power measurement unit 120 may be connected to the power source 10 to measure the AC power, measure a peak or waveform of the AC power, and measure (peak or waveform of) the AC power input to the power control unit 110. For example, the power measurement unit 120 may measure AC power input to the SCR, and may measure (the peak or waveform of) AC voltage and/or AC. Through this control, it is possible to detect fluctuations in the AC power input to the power control unit 110 (e.g., AC power input to the SOC).

Here, the power control unit 110 may control the phase of the AC power by compensating a phase angle α for it according to a difference between reference power value R and measured value M measured by the power measurement unit 120. Here, the reference power value R may be the rated power (or the rated voltage and/or the rated current) of the heating source 20 and/or the rated power of an external power source 10, and may be (a value of) power used on average (or generally) for the heating source 20 or supplied when connected to the external power source 10. Even if the AC power is supplied from the power source 10 in accordance with the reference power value R due to replacement of the power source 10 or the occurrence of other unstable factors, a difference may occur in the measured value M measured by the power measurement unit 120, and the measured value M measured by the power measurement unit 120 may be different from the reference power value R. In this case, the difference between the reference power (value) and the measurement (value) measured by the power measurement unit 120 may have the same period (or frequency) and different peak or waveform, and a difference may occur in voltage V, a difference may occur in current I, or a difference may occur in both voltage V and current I.

Generally, in a device that heats an object to be heated (e.g., a substrate) by applying (or supplying) power to the heating source 20, such as a thermal processing system 200, AC power supplied from the power source 10 is fixed to an initial setting state and used, and the amount of power supplied to the heating source 20 is adjusted by simply controlling the phase of the AC power arithmetically (or by a formula) to match the output (intensity) of the heating source 20 required for heating the object to be heated. As a result, when the AC power supplied from the power source 10 to the means (or power control unit) for controlling the phase of the AC power fluctuates due to the occurrence of other unstable factors during use of the thermal processing system 200, etc., it becomes impossible to heat the object to be heated to a target temperature (or according to a set temperature), and the reliability of thermal processing deteriorates.

In addition, when replacing the power source 10 of the thermal processing system 200, etc. or using a different power source 10 depending on the location where the thermal processing system 200, etc. is installed, the AC power supplied from the power source 10 may vary depending on the connected power source 10. For this reason, when power is controlled in a conventional manner, thermal processing performance (or heating performance) may vary depending on which power source 10 is connected. When intensity of the AC power supplied from the power source 10 can be changed by producing power internally, the intensity of the AC power may be adjusted so that the reference power that fits a prescribed formula is supplied from the power source 10, but when using the external power source 10 supplied with a fixed intensity of the AC power, the intensity of the AC power cannot be adjusted, and thus there is a difficulty in creating a new formula appropriate for the connected power source 10.

However, when the power control unit 110 controls the phase of the AC power by compensating the phase angle α for it according to the difference between the reference power value R and the measured value M measured by the power measurement unit 120, even if the fluctuation in the AC power occurs, the required amount of power can be stably supplied to the heating source 20 according to the need (or required amount of power) of the heating source 20 according to one control formula without the need to adjust the intensity of the AC power. That is, there is no need to create each formula according to the connected power source 10, and even if the AC power supplied (or input) from the power source 10 to the power control unit 110 fluctuates due to the occurrence of other unstable factors during use of the thermal processing system 200, etc., the amount of power required for the heating source 20 may be supplied within a tolerance range, and the object to be heated may be subjected to thermal processing (or heating) according to the target temperature (or set temperature).

Therefore, the power control device 100 for temperature control according to the present disclosure measures the AC power supplied from the power source 10 through the power measurement unit 120 and compensates the phase angle a for phase control of the AC power according to the difference between the reference power value R and the measured value M measured by the power measurement unit 120, thereby capable of stably supplying the required amount of power to the heating source 20 according to the needs of the heating source 20. That is, the amount of power required for the heating source 20 may be supplied within the tolerance range regardless of the fluctuation of the AC power input to the power control unit 110.

In addition, the power control unit 110 may include a phase calculation unit 111 that calculates a control phase R_{Pa} for the AC power from the reference power value R according to an amount of applied power to the heating source 20 and a phase angle compensation unit 112 that calculates the phase angle α from the difference value between the reference power value R and the measured value M measured by the power measurement unit 120 and compensates the phase angle α for the control phase R_{Pa} calculated by the phase calculation unit 111. The phase calculation unit 111 may calculate the control phase R_{Pa} for the AC power from the reference power value R according to the amount of applied power to the heating source 20. Here, the amount of applied power to the heating source 20 may be the amount of power required for the heating source 20, and the control phase R_{Pa} for the AC power calculated from the reference power value R may be the control phase R_{Pa} before the phase angle α compensation, and may be one obtained by dividing a period of the AC power by a certain ratio in the waveform of the reference power according to the amount of applied power. For example, the phase calculation unit 111 may calculate the control phase R_{Pa} for the AC power in proportion to the amount of applied power. When the amount of applied power increases, the control phase R_{Pa} for the AC power may also increase, and when the amount of applied power decreases, the control phase R_{Pa} for the AC power may also decrease.

The phase angle compensation unit 112 may calculate the phase angle a from a difference value between the reference power value R and the measured value M measured by the power measurement unit 120 and compensate the phase angle α for the control phase R_{Pa} calculated by the phase calculation unit 111, and may generate a compensated control phase M_{Pa} by compensating the phase angle α for the control phase R_{Pa} calculated by the phase calculation unit 111. Through this, regardless of the fluctuation of the AC power, power (amount) matching the amount of applied power can be supplied to the heating source 20 with an error within an allowable range.

In addition, the power control unit 110 may further include a power amount setting unit 113 that sets the amount of applied power according to the output of the heating source 20. The power amount setting unit 113 may set the amount of applied power according to the required (or necessary) output (e.g., energy emission intensity or radiation intensity) of the heating source 20, calculate the amount of applied power and set by receiving output information of the heating source 20, and set the amount of applied power by receiving information on the amount of applied power calculated according to the output of the heating source 20. For example, when the power control device 100 is used in the thermal processing system 200, the (set) output of the heating source 20 required may be determined according to the temperature of the substrate (to be measured) 21 so that the substrate 21 may be subjected to thermal processing (or heating) according to the set temperature (or target temperature), and the amount of applied power, which may be the output of the heating source 20, may be set in the power amount setting unit 113.

In this case, the phase calculation unit 111 may calculate the control phase R_{Pa} for the AC power from the reference power value R according to the amount of applied power set in the power amount setting unit 113.

In addition, the phase angle compensation unit 112 may calculate the phase angle α in proportion to the difference value between the reference power value R and the measured value M measured by the power measurement unit 120. For example, when the difference between the peak of the reference power and the peak of the measured power measured by the power measurement unit 120 is large, it may be compensated with a large phase angle α in order to compensate the large power difference so that the the power amount obtained by applying the phase angle control PAC to the measured power measured by the power measurement unit 120 is equal to the power amount obtained by controlling the reference power with the control phase R_{Pa} for the AC power calculated from the reference power value R. In contrast, when the difference between the peak of the reference power and the peak of the measured power measured by the power measurement unit 120 is small, it may be compensated with a small phase angle α in order to compensate the small power difference so that the power amount obtained by applying the phase angle control PAC to the measured power measured by the power measurement unit 120 is equal to the the power amount obtained by controlling the reference power with the control phase R_{Pa} for the AC power calculated from the reference power value R.

By calculating the phase angle α in this way and compensating the phase angle α for the control phase R_{Pa} for the AC power (i.e., to the control phase calculated by the phase calculation unit) calculated from the reference power value R, the compensated control phase M_{Pa} may be obtained, and the the amount of power obtained by controlling the measured power measured by the power measurement unit 120 with the compensated control phase M_{Pa} may be equal to the amount of power obtained by controlling the reference power with the control phase R_{Pa} for the AC power calculated from the reference power value R.

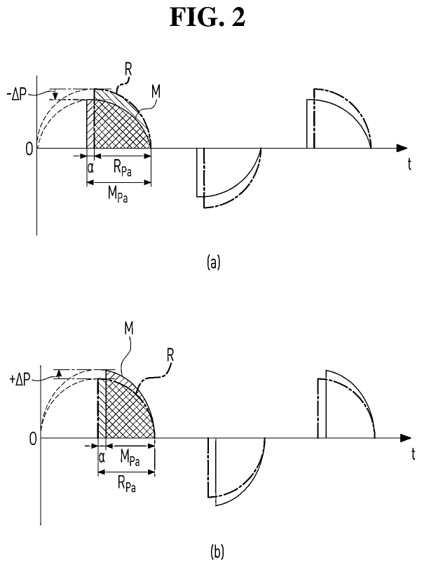

FIG. 2 is a conceptual diagram for describing phase angle compensation according to an embodiment of the present disclosure, (a) of FIG. 2 illustrates addition of phase angles, and (b) of FIG. 2 illustrates subtraction of phase angle.

Referring to FIG. 2, the phase angle compensation unit 112 may add the phase angle α to the control phase R_{Pa} calculated by the phase calculation unit 111 when the difference between the reference power value R and the measured value M measured by the power measurement unit 120 is a positive number, and may subtract the phase angle α from the control phase R_{Pa} calculated by the phase calculation unit 111 when the difference between the reference power value R and the measured value M measured by the power measurement unit 120 is a negative number.

When the difference between the reference power value R and the measured value M measured by the power measurement unit 120 is a positive number, the reference power value R is greater than the measured value M measured by the power measurement unit 120, and thus, when the reference power and the measured power measured by the power measurement unit 120 are controlled with R_{Pa} calculated by the phase calculation unit 111 in the same way as above, the amount of power obtained by controlling the reference power with the control phase R_{Pa} calculated by the phase calculation unit 111 becomes greater than the amount of power obtained by controlling the measured power measured by the power measurement unit 120 with the control phase R_{Pa} calculated by the phase calculation unit 111. Therefore, in order to increase the the amount of power obtained by applying the phase angle control (PAC) to the measured power measured by the power measurement unit 120 to become the same as the amount of power obtained by controlling the reference power with the control phase R_{Pa} calculated by the phase calculation unit 111, the phase angle α may be added to the control phase R_{Pa} calculated by the phase calculation unit 111 so that the compensated control phase M_{Pa} is greater than the control phase R_{Pa} calculated by the phase calculation unit 111.

In contrast, when the difference between the reference power value R and the measured value M measured by the power measurement unit 120 is a negative, the reference power value R is smaller than the measured value M measured by the power measurement unit 120, and thus, when the reference power and the measured power measured by the power measurement unit 120 are controlled with R_{Pa} calculated by the phase calculation unit 111 in the same way as above, the amount of power obtained by controlling the reference power with the control phase R_{Pa} calculated by the phase calculation unit 111 becomes greater than the amount of power obtained by controlling the measured power measured by the power measurement unit 120 with the control phase R_{Pa} calculated by the phase calculation unit 111. Therefore, in order to decrease the amount of power obtained by applying the phase angle control (PAC) to the measured power measured by the power measurement unit 120 to become the same as the amount of power obtained by controlling the reference power with the control phase R_{Pa} calculated by the phase calculation unit 111, the phase angle α may be subtracted from the control phase R_{Pa} calculated by the phase calculation unit 111 so that the compensated control phase M_{Pa} is smaller than the control phase R_{Pa} calculated by the phase calculation unit 111.

Here, the power source 10 may supply three-phase AC power. Three-phase AC power may have different peaks, etc. among each phase. The difference from the reference power value R may vary depending on which phase AC power is being supplied.

In the conventional method, when all three phases of AC power are used, since AC power with different peaks is supplied with a phase difference and fluctuations in AC power occur in real time (or for each phase of the three phases), it is impossible even to create a new formula while initially setting the thermal processing system 200, etc. In addition, when using single-phase AC power by selecting any one of the three phases of AC power, a new formula can be created. However, depending on which of the three phases is selected, the problem of having to create a new formula each time arises.

However, in the present disclosure, by measuring the AC power input to the power control unit 110 in real time (or at regular intervals) through the power measurement unit 120, it may be compensated with the phase angle α according to the difference between the measured value M measured by the power measurement unit 120 and the reference power value R to supply an amount of power within the tolerance range for the amount of applied power (always) to the heating source 20, and the reliability of thermal processing can be improved.

For example, the power measurement unit 120 may measure AC power of each phase, and the power control unit 110 may respectively control a phase of the AC power of each phase by respectively compensating the phase angle α according to the difference between the reference power value R and the measured value M measured by the power measurement unit 120, for the AC power of each phase. The power measurement unit 120 may measure the AC power of each phase and may measure the AC power input to the power control unit 110 in real time.

In addition, the power control unit 110 may respectively control the phase of the AC power of each phase by respectively compensating the phase angle a according to the difference between the reference power value R and the measured value M measured by the power measurement unit 120, for the AC power of each phase. Since peaks, etc. are different among between the three phases of AC power, the difference from the reference power value R may vary depending on which phase AC power is supplied. For this reason, the phase of the AC power of each phase may be respectively controlled by respectively compensating the phase angle α according to the difference between the reference power value R and the measured value M measured by the power measurement unit 120, for the AC power of each phase. Accordingly, even when all three phases of AC power are used by compensating the phase angle α for each AC power of each phase according to the difference between the measured value M measured by the power measurement unit 120 and the reference power value R, an amount of power within the tolerance range for the amount of applied power may (always) be supplied to the heating source 20.

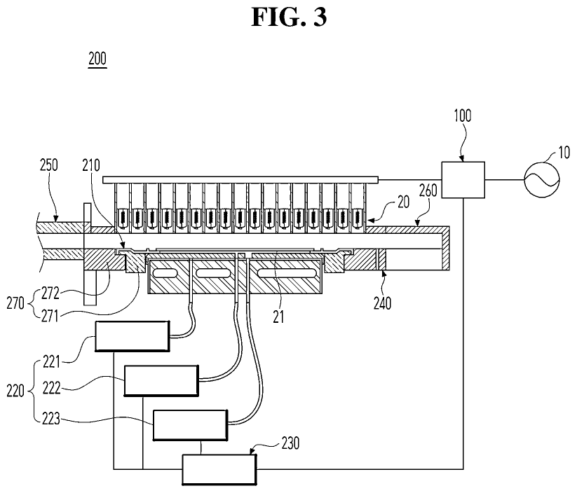

FIG. 3 is a schematic cross-sectional view illustrating a thermal processing system according to another embodiment of the present disclosure.

Referring to FIG. 3, a thermal processing system according to another embodiment of the present disclosure will be described in more detail. Matters that overlap with those previously described in relation to the power control device for temperature control according to an embodiment of the present disclosure will be omitted.

A thermal processing system 200 according to another embodiment of the present disclosure may include the power control device 100 for temperature control according to an embodiment of the present disclosure, a substrate support part 210 provided opposite the heating source 20 and supporting the substrate 21, a temperature measurement unit 220 that measures a temperature of the substrate 21, and a heating intensity calculation unit 230 that calculates the output of the heating source 20 according to the temperature of the substrate 21.

The power control device 100 for temperature control may be the power control device 100 for temperature control according to an embodiment of the present disclosure. The thermal processing system 200 including this power control device 100 can stably provide the required amount of power to the heating source 20 in accordance with the required (setting) output of the heating source 200 while controlling the output of the heating source (e.g., energy emission intensity or radiation intensity) that heats the substrate according to the temperature of the substrate. Through this, even if there is the fluctuation in the AC power input to the power control unit, the difference between the (set) output of the heating source 20 required at each point in time (or period) and the actual output of the heating source 20 may be maintained within an allowable range and the substrate 21 may be heated to a temperature close to (or similar to) a target temperature of the substrate 21, and accordingly, the reliability of thermal processing of the substrate 21 can be improved.

The substrate support part 210 may be provided opposite the heating source 20 and may support the substrate 21. For example, the substrate support part 210 may be provided in an internal space of a chamber 240 and may support the substrate 21 within the chamber 240. Here, the substrate support part 210 may include a ring-shaped edge ring. The edge ring may be designed to reduce a contact area with the substrate 21 and may support a lower-surface edge of the substrate 21. By reducing the contact area between the edge ring and the substrate 21, a heating state near the edge of the substrate 21 may be simplified, and thus an edge high/low effect may be reduced and particle contaminants in the chamber 240 may be reduced. In this case, the substrate 21 may include a wafer.

Meanwhile, the edge ring has a groove to prevent the temperature of the edge area of the substrate 21 from being relatively low due to a process gas, and may also make the temperature of the edge area of the substrate 21 uniform.

The temperature measurement unit 220 may measure the temperature of the substrate 21, may measure the temperature from the center of the substrate 21 to the edge thereof, and may measure the temperature at regular intervals. For example, the temperature measurement unit 220 may include temperature measuring sensors 221, 222, and 223, such as pyrometers. The temperature measurement sensors 221, 222, and 223 may measure the temperature of the substrate 21 by receiving radiation (or infrared light) emitted from the lower surface of the substrate 21 below the substrate 21, which is on an opposite side of the heating source 20. In this case, the pyrometer may temperature the temperature using the black body radiation theory according to light emitted from the object and detected, and the temperature measurement process is widely known, and thus detailed description thereof will be omitted.

The heating intensity calculation unit 230 may calculate the output of the heating source 20 (e.g., energy emission intensity or radiation intensity) according to the temperature of the substrate 21, and may calculate output (intensity) of the heating source 20, such as energy emission intensity or radiation intensity, that can heat the substrate 21 to the target temperature according to the temperature of the substrate 21 measured by the temperature measurement unit 220. When the substrate 21 is heated using the output of the heating source 20 calculated in this way, the substrate 21 may be subjected to thermal processing (or heating) according to the set temperature (or target temperature). In this case, the (set) output of the heating source 20 calculated by the heating intensity calculation unit 230 is transmitted to the power amount setting unit 113, and the amount of applied power to the heating source 20 may be set in the power amount setting unit 113 according to the output of the heating source 20 calculated by the heating intensity calculation unit 230.

For example, the heating source 20 may include a plurality of lamps disposed above the substrate support part 210, and may provide light energy toward the substrate 21 supported on the substrate support part 210. Here, the plurality of lamps may provide radiant energy to the internal space of the chamber 240, and may heat the substrate 21 by transferring the radiant energy to the substrate 21. In this case, the plurality of lamps may include halogen lamps, and may generate radiant heat flowing into the internal space of the chamber 240 through a window of the chamber 240. In addition, the plurality of lamps may be arranged in a plurality of regions that are classified together into several control groups, and the temperature of the substrate 21 can be controlled by controlling the lamp using a temperature control algorithm.

Meanwhile, the heating source 20 may have an area larger than that of the substrate 21, and at least a portion of the heating source 20 may be provided in an upper part of the groove of the edge ring to provide light energy toward the groove. Through this configuration, the process gas flowing into the groove may be heated, and accordingly, the temperature of an area of the edge of the substrate 21 may be prevented from being lowered by the process gas that is not sufficiently heated. For example, the lamps may be located above the groove of the edge ring, and among the plurality of lamps, the lamp(s) located above the groove may be grouped together.

Here, the amount of applied power to the heating source 20 may be determined according to the (set) output of the heating source 20 calculated by the heating intensity calculation unit 230. The output of the heating source 20 may be controlled according to the amount of power applied (or supplied) to the heating source 20, and the amount of applied power to the heating source 20 may be determined so that the output of the heating source 20 is the output of the heating source 20 calculated by the heating intensity calculation unit 230. Accordingly, the amount of applied power to the heating source 20 may be determined according to the output of the heating source 20 calculated by the heating intensity calculation unit 230. The amount of applied power determined in this way may be set in the power amount setting unit 113 to heat (or perform thermal processing on) the substrate 21 with the output of the heating source 20 calculated by the heating intensity calculation unit 230.

Meanwhile, the thermal processing system 200 of the present disclosure invention may further include a chamber 240 having an internal space where thermal processing is performed, a gas supply unit 250 provided on one side of the chamber 240 to supply the process gas, and an exhaust unit 260 provided on the other side of the chamber 240 opposite the gas supply unit 250 and exhausting the residual gas of the chamber 240.

The chamber 240 may have an internal space where thermal processing is performed, may define a processing space, and may form a process atmosphere. For example, a window made of quartz may be formed on an upper surface of the chamber 240, and the heating source 20 may be disposed on the window.

The gas supply unit 250 may be provided on one side of the chamber 240 and may supply the process gas. Here, the gas supply unit 250 may supply the process gas at a temperature lower than the temperature of a thermal processing process, and may supply the process gas to the internal space of the chamber 240 (i.e., the space between the window of the chamber and the substrate) while performing the thermal processing process. In this case, the process gas may be supplied to the internal space of the chamber 240 to react on the substrate 21, and the residual gas remaining after the reaction may be exhausted (or discharged) through the exhaust unit 260.

The exhaust unit 260 may be provided on the other side of the chamber 240 opposite to the gas supply unit 250, and may exhaust the residual gas within the chamber 240. Here, exhaust holes of the exhaust unit 260 may face injection ports of the gas supply unit 250, and a linear gas flow may be formed by the injection ports of the gas supply unit 250 and the exhaust holes of the exhaust unit 260 facing each other. For example, the residual gas may be exhausted through the exhaust holes of the exhaust unit 260 within the chamber 240 through exhaust ports connected to a vacuum pump (not shown).

In addition, the thermal processing system 200 of the present disclosure may further include a rotation support part 270 that rotates the substrate support part 210.

The rotation support part 270 may rotate the substrate support part 210, may include a support ring 271 on which the edge ring is supported, and may rotate the supported edge ring. The support ring 271 may support the edge ring and may have a ring shape or a cylinder shape, and the edge ring may be supported while surrounding the support ring 271. For example, the support ring 271 may be made of quartz, and may be coated with silicon (or silicon) as a shielding material to block radiation from the heating source 20 that may interfere with temperature measurement of the substrate 21, so that the support ring 271 may be made opaque in a frequency range of the temperature measurement sensor (e.g., a frequency range of the pyrometer).

In addition, the rotation support part 270 may rotate the supported edge ring to rotate the substrate 21, and may also elevate (or vertically move) the edge ring and/or the substrate 21. For example, the rotation support part 270 may rotate the substrate 21 while performing the thermal processing process, may rotate the substrate 21 about 90 times per minute, and may rotate the edge ring by rotating the support ring 271 coupled to a drive system (not shown). Here, the rotation support part 270 may further include a base plate 272 supporting the support ring 271, and the drive system (not shown) may be provided on the base plate 272.

Here, the process gas may be supplied parallel to an upper surface of the substrate 21, and may be supplied parallel to the upper surface of the substrate 21 in the lateral direction (or side) of the substrate 21 rather than being supplied perpendicular to the upper surface of the substrate 21. Through this supply of process gas, a laminar flow may be formed on the substrate 21. That is, the process gas may flow parallel to the upper surface of the substrate 21 along a substantially flat upper surface formed by the upper surface of the edge ring and the upper surface of the substrate 21, the residual gas may be discharged through the exhaust unit 260 after the process gas reacts on the substrate 21, and a laminar flow may be formed on the substrate 21 through the flow of these gases.

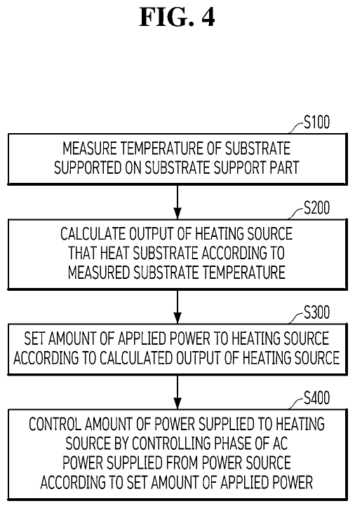

FIG. 4 is a flowchart illustrating a temperature control method of a thermal processing system according to yet another embodiment of the present disclosure.

Referring to FIG. 4, a temperature control method of a thermal processing system according to yet another embodiment of the present disclosure will be described in more detail. Matters that overlap with those previously described in relation to the power control device for temperature control according to an embodiment of the present disclosure and the thermal processing system according to another embodiment of the present disclosure will be omitted.

A temperature control method of the thermal processing system according to yet another embodiment of the present disclosure may include measuring a temperature of a substrate supported on a substrate support part (S100); calculating an output of a heating source that heats the substrate according to the measured temperature of the substrate (S200); setting an amount of applied power to the heating source according to the calculated output of the heating source (S300); and controlling an amount of power supplied to the heating source by controlling a phase of AC power supplied from a power source according to the set amount of applied power (S400).

First, the temperature of the substrate supported on the substrate support is measured (S100). The substrate supported on the substrate support part may be heated to be subjected to thermal processing through the heating source, and the temperature of the substrate may be measured through a temperature measurement unit in order to heat the substrate to a target temperature (or according to a set temperature).

Next, an output of the heating source that heats the substrate is calculated according to the measured temperature of the substrate (S200). The output (e.g., energy emission intensity or radiation intensity) of the heating source that heats the substrate may be calculated according to the temperature of the substrate measured through the heating intensity calculation unit, and the output of the heating source capable of heating the substrate to the target temperature (or set temperature) may be calculated according to the temperature of the substrate measured by the temperature measurement unit. When the substrate is heated with the (set) output of the heating source calculated in this way, the substrate may be subjected to thermal processing (or heated) according to the set temperature (or target temperature).

Next, the amount of applied power to the heating source is set according to the calculated output of the heating source (S300). The amount of applied power to the heating source may be set in the power amount setting unit according to the calculated output of the heating source (e.g., energy emission intensity or radiation intensity), and the calculated (set) output of the heating source is transmitted to the power amount setting unit, so that the amount of applied power to the heating source may be set according to the calculated output of the heating source. The output of the heating source may be controlled according to the power (amount) applied (or supplied) to the heating source, and the amount of applied power to the heating source may be determined so that the output of the heating source is the output of the heating source calculated by the heating intensity calculation unit. Accordingly, the amount of applied power to the heating source may be determined according to the calculated output of the heating source. The amount of applied power determined in this way is set in the power amount setting unit, and the substrate may be heated (or subjected to thermal processing) with the calculated output of the heating source.

In addition, the amount of power supplied to the heating source is controlled by controlling the phase of the AC power supplied from the power source according to the set amount of applied power (S400). The amount of power supplied to the heating source may be controlled by controlling the phase of AC power supplied from the power source through the power control unit, and the amount of power supplied to the heating source may be controlled using the thyristor such as the SCR by applying the PAC method. Here, the power control unit may adjust (or control) the amount of power supplied to the heating source according to the set amount of applied power so that the same amount of power (amount) as the set amount of applied power may be supplied to the heating source, and the phase of the AC power may be controlled so that the amount of power supplied to the heating source is the set amount of applied power. For example, the power control unit may control the phase of the AC power by changing the timing of the gate current applied to the gate of the SCR into which the AC power is input, and through this, the amount of power supplied to the source may be adjusted. Here, power P may be a product of voltage V and current I, and the AC power may include AC voltage and AC.

Here, the controlling the amount of power supplied to the heating source (S400) may include a process of measuring the AC power (S410) and a process of controlling a phase of the AC power by compensating a phase angle according to a difference between the measured value of the AC power and a reference power value (S420).

The AC power may be measured (S410). The AC power may be measured through the power measurement unit connected to the power source, the peak or wave form of the AC power may be measured, and (the peak or wave form of) the AC power input to the power control unit may be measured. For example, the power measurement unit may measure AC power input to the SCR, and may measure (the peak or waveform of) AC voltage and/or AC. Through these measurements, it is possible to detect fluctuations in AC power input to the power control unit (e.g., the SOC).

In addition, the phase of the AC power may be controlled by compensating the phase angle α according to the difference between the measured value of the AC power and the reference power value (S420). The power control unit may control the phase of the AC power by compensating the phase angle α according to the difference between the measured value M of the AC power and the reference power value R. Here, the reference power value R may be the rated power (or the rated voltage and/or the rated current) of the heating source and/or the rated power of an external power source, and may be (a value of) power used on average (or generally) for the heating source or supplied when connected to the external power source. Even if the AC power is supplied from the power source in accordance with the reference power value R due to replacement of the power source or the occurrence of other unstable factors, a difference may occur in the measured value M measured by the power measurement unit, and the measured value M measured by the power measurement unit may be different from the reference power value R. In this case, the difference between the reference power (value) and the measurement (value) measured by the power measurement unit may have the same period (or frequency) and different peak or waveform, and a difference may occur in voltage V, a difference may occur in current I, or a difference may occur in both voltage V and current I.

When the phase of the AC power is controlled by compensating the phase angle α according to the difference between the measured value M measured and the reference power value, even if the fluctuation in the AC power occurs, the required amount of power can be stably supplied to the heating source according to the need (or required amount of power) of the heating source according to one control formula without the need to adjust the intensity of the AC power. That is, there is no need to create each formula according to the connected power source, and even if the AC power supplied (or input) from the power source to the power control unit fluctuates due to the occurrence of other unstable factors during use of the thermal processing system, etc., the amount of power required for the heating source may be supplied within a tolerance range, and the substrate may be subjected to thermal processing (or heating) according to the target temperature (or set temperature).

Accordingly, in the temperature control method for the thermal processing system of the present disclosure, the temperature of the substrate supported on the substrate support part is measured to calculate the output (or intensity) of the heating source to heat the substrate to the target temperature according to the measured temperature of the substrate, then an amount of applied power to the heating source is set according to the calculated output of the heating source, and a phase of the AC power supplied from the power source is controlled according to the set amount of applied power, thereby compensating the phase angle according to the difference between the measured value M of the AC power obtained by measuring the AC power and the reference power value R to control the phase of the AC power, in the process S400 of controlling the amount of power supplied to the heating source, so that the amount of power supplied to the heating source may be supplied with an error within the allowable range from the amount of applied power regardless of fluctuations in AC power. Through this, the difference between the (set) output of the heating source calculated at each point in time of measuring the temperature of the substrate and the actual output of the heating source may be maintained within an allowable range, and the substrate may be heated to a temperature close to the target temperature of the substrate to be subjected to thermal processing.

The process of controlling the phase of the AC power (S420) may include a process of calculating a control phase R_{Pa} for the AC power from the reference power value R according to the set amount of applied power (S421), a process of calculating the phase angle α using a difference value between the reference power value R and the measured value of the AC power (S422), and a process of compensating the calculated phase angle α to the calculated control phase R_{Pa} (S423).

The control phase R_{Pa} for the AC power may be calculated from the reference power value R according to the set amount of applied power (S421). The control phase R_{Pa} for the AC power may be calculated from the reference power value R according to the set amount of applied power through the phase calculation unit. Here, the set amount of applied power may be the amount of power required for the heating source. The control phase R_{Pa} for the AC power calculated from the reference power value R may be the control phase R_{Pa} before the phase angle α compensation and may be one obtained by dividing a period of the AC power by a certain ratio in the waveform of the reference power according to the amount of applied power. For example, the phase calculation unit may calculate the control phase R_{Pa} for the AC power in proportion to the amount of applied power. When the amount of applied power increases, the control phase R_{Pa} for the AC power may also increase, and when the amount of applied power decreases, the control phase R_{Pa} for the AC power may also decrease.

Next, the phase angle α may be calculated using the difference between the reference power value R and the measured value M of the AC power (S422). Through the phase angle compensation unit, the phase angle α may be calculated from the difference value between the reference power value R and the measured value M measured by the power measurement unit 120, and, by calculating the phase angle a, the control phase R_{Pa} calculated by the phase calculation unit 111 may be compensated with the phase angle α.

In addition, the calculated control phase R_{Pa} may be compensated with the calculated phase angle α (S423). The compensated control phase M_{Pa} may be generated by compensating the phase angle α for the control phase R_{Pa} calculated by the phase calculation unit. Through this, regardless of the fluctuation of the AC power, power (amount) matching the amount of applied power may be supplied to the heating source with an error within an allowable range.

In the process S422 of calculating the phase angle, the phase angle may be calculated in proportion to the difference value between the measured value of the AC power and the reference power value. The phase angle compensation unit may calculate the phase angle α in proportion to the difference value between the reference power value R and the measured value M of the AC power. For example, when the difference between the peak of the reference power and the peak of the measured AC power is large, it may be compensated with a large phase angle α in order to compensate the large power difference so that the power amount obtained by applying the phase angle control PAC to the measured AC power is equal to the power amount obtained by controlling the reference power with the calculated control phase R_{Pa}. In contrast, when the difference between the peak of the reference power and the peak of the measured AC power is small, it may be compensated with a small angle α in order to compensate the small power difference so that the the power amount obtained by applying the phase angle control PAC to the measured AC power is equal to the power amount obtained by controlling the reference power with the calculated control phase R_{Pa}.

By calculating the phase angle α in this way and compensating the phase angle α for the calculated control phase R_{Pa}, the compensated control phase M_{Pa} can be obtained, and the amount of power obtained by controlling the measured AC power with the compensated control phase M_{Pa} may be equal to the amount of power obtained by controlling the reference power with the calculated control phase R_{Pa}.

The process of compensating the calculated phase angle (S423) may include a process of adding the calculated phase angle to the calculated control phase when a value obtained by subtracting the measured value of the AC power from the reference power value is a positive number (S423a) and a process of subtracting the calculated phase angle from the calculated control phase when the value obtained by subtracting the measured value of the AC power from the reference power value is a negative number (S423b).

When the value obtained by subtracting the measured value of the AC power from the reference power value is a positive number, the calculated phase angle may be added to the calculated control phase (S423a). When the value obtained by subtracting the measured value M of the AC power, which is measured, from the reference power value R is a positive number, the reference power value R is greater than the measured value M measured by the power measurement unit 120, and thus, when the reference power and the measured power are controlled with the calculated R_{Pa} in the same way as above, the amount of power obtained by controlling the reference power with the calculated control phase R_{Pa} becomes greater than the amount of power obtained by controlling the measured power of the AC power with the calculated control phase R_{Pa}. Therefore, in order to increase the amount of power obtained by applying the phase angle control (PAC) to the measured AC power to become the same as the amount of power obtained by controlling the reference power with the calculated control phase R_{Pa}, the phase angle a may be added to the calculated control phase R_{Pa} so that the compensated control phase M_{Pa} is greater than the calculated control phase R_{Pa}.

In addition, when the value obtained by subtracting the measured value of the AC power from the reference power value is a negative number, the calculated phase angle may be subtracted from the calculated control phase (S423b). When the value obtained by subtracting the measured value M of the measured AC power from the reference power value R is a negative number, the reference power value R is smaller than the measured value M of the AC power, and thus, when the reference power and the measured power are controlled with the calculated control phase R_{Pa} in the same way as above, the amount of power obtained by controlling the reference power with the calculated control phase R_{Pa} becomes smaller than the amount of power obtained by controlling the measured power of the AC power with the calculated control phase R_{Pa}. Therefore, in order to decrease the amount of power obtained by applying the phase angle control (PAC) to the measured power of the AC power to become the same as the amount of power obtained by controlling the reference power with the calculated control phase R_{Pa}, the phase angle α may be subtracted from the calculated control phase R_{Pa} so that the compensated control phase M_{Pa} is smaller than the calculated control phase R_{Pa}.

The power source may supply three-phase AC power. In the process S420 of controlling the phase of the AC power, a phase of the AC power of each phase may be respectively controlled by respectively compensating a phase angle of each phase according to the difference between the measured value of the AC power measured for the AC power of each phase and the reference power value. The power source may supply three-phase AC power, and the three-phase AC power may have different peaks, etc. among each phase. The difference from the reference power value R may vary depending on which phase AC power is being supplied.

In the conventional method, when all three phases of AC power are used, since AC power with different peaks is supplied with a phase difference and fluctuations in AC power occur in real time (or for each phase of the three phases), it is impossible even to create a new formula while initially setting the thermal processing system, etc. In addition, when using single-phase AC power by selecting any one of the three phases of AC power, a new formula can be created. However, depending on which of the three phases is selected, the problem of having to create a new formula each time arises.

However, in the present disclosure, by measuring the AC power input to the power control unit in real time (or at regular intervals) through the power measurement unit, it may be compensated with the phase angle α according to the difference between the measured value M of the AC power and the reference power value R to supply an amount of power within the tolerance range from the amount of applied power (always) to the heating source, and the reliability of thermal processing can be improved.

For example, in the process S410 of measuring the AC power, the AC power of each phase may be measured through the power measurement unit. In the process S420 of controlling the phase of the AC power, through the power control unit, the phase of the AC power of each phase may be respectively controlled by respectively compensating the phase angle α of the AC power of each phase according to the difference between the reference power value R and the measured value M of the AC power measured for the AC power of each phase. The power measurement unit may measure the AC power of each phase, and may measure the AC power input to the power control unit in real time.

In addition, the power control unit may respectively control the phase of the AC power of each phase by respectively compensating the phase angle α for each phase according to the difference between the reference power value R and the measured value M of the AC power. Since peaks, etc. are different between the three phases of AC power, the difference from the reference power value R may vary depending on which phase AC power is supplied, the phase of the AC power of each phase may be controlled by compensating the phase angle α for the AC power of each phase according to the difference between the reference power value R and the measured value M of the AC power. Accordingly, even when all three phases of AC power are used by compensating the phase angle α for each AC power of each phase of according to the difference between the measured value M of the AC power and the reference power value R, an amount of power within the tolerance range from the amount of applied can (always) be supplied to the heating source.

As described above, in the present disclosure, the AC power supplied from the power source through the power measurement unit is measured and compensates the phase angle for phase control of the AC power according to the difference between the reference power value and the measured value, so that the required amount of power can be stably supplied to the heating source according to the needs of the heating source and the amount of power required for the heating source can be supplied within the tolerance range regardless of fluctuations in the AC power input to the power control unit. When using such a power control device in the thermal processing systems, the required amount of power can be stably provided to the heating source in accordance with the required (setting) output of the heating source while controlling the output of the heating source that heats the substrate according to the temperature of the substrate, and even if there is the fluctuation in the AC power input to the power control unit, the difference between the output of the heating source required at each point in time and the actual output of the heating source can be maintained within an allowable range, and the substrate can be heated to a temperature close to (or similar to) a target temperature of the substrate. Accordingly, the reliability of thermal processing of the substrate can be improved. In addition, in the process of measuring the temperature of the substrate supported on a substrate support part, calculating the output of the heating source to heat the substrate to the target temperature according to the measured temperature of the substrate, setting an amount of applied power to the heating source according to the calculated output of the heating source, and controlling the amount of power supplied to the heating source by controlling a phase of AC power supplied from the power source according to the set amount of applied power while controlling the temperature of the thermal processing system, the phase of the AC power may be controlled by compensating the phase angle according to the difference between the measured value of the AC power and the reference power value so that the amount of power supplied to the heating source may be supplied with an error within the allowable range from the amount of applied power regardless of fluctuations in AC power. Through this, the difference between the output of the heating source calculated at each point in time of measuring the temperature of the substrate and the actual output of the heating source can be maintained within an allowable range, and the substrate can be heated to a temperature close to the target temperature of the substrate to be subjected to thermal processing.

The power control device for temperature control according to an embodiment of the present disclosure measures AC power supplied from the power source through the power measurement unit and compensates the phase angle for phase control of the AC power according to the difference between the reference power value and the measured value, thereby capable of stably supplying a required amount of power to the heating source according to the needs (or required amount of power) of the heating source. That is, the amount of power required for the heating source can be supplied within a tolerance range regardless of the fluctuation in the AC power input to the power control unit.

The thermal processing system including this power control device can stably provide the required amount of power to the heating source in accordance with the required (setting) output of the heating source while controlling the output of the heating source that heats the substrate according to the temperature of the substrate. Through this, even if there is the fluctuation in the AC power input to the power control unit, the difference between the (set) output of the heating source required at each point in time (or period) and the actual output of the heating source can be maintained within an allowable range and the substrate can be heated to a temperature close to (or similar to) a target temperature of the substrate, and accordingly, the reliability of thermal processing of the substrate can be improved.

In addition, in the temperature control method for the thermal processing system of the present disclosure, in the process of measuring the temperature of the substrate supported on a substrate support part, calculating the output of the heating source to heat the substrate to the target temperature according to the measured temperature of the substrate, setting an amount of applied power to the heating source according to the calculated output of the heating source, and controlling the amount of power supplied to the heating source by controlling the phase of the AC power supplied from the power source according to the set amount of applied power, the phase of the AC power is controlled by compensating the phase angle according to the difference between the measured value of the AC power and the reference power value, thereby capable of supplying the amount of power supplied to the heating source with an error within the allowable range from the amount of applied power regardless of fluctuations in AC power. Through this, the difference between the output of the heating source calculated at each point in time of measuring the temperature of the substrate and the actual output of the heating source can be maintained within an allowable range, and the substrate can be heated to a temperature close to the target temperature of the substrate to be subjected to thermal processing.

Although the power control device for temperature control, the thermal processing system having the same, and the temperature control method for the thermal processing system have been described with reference to the specific embodiments, they are not limited thereto. Therefore, it will be readily understood by those skilled in the art that various modifications and changes can be made thereto without departing from the spirit and scope of the present invention defined by the appended claims.

### REFERENCE NUMERALS LIST

10: power source
20: heating source
21: substrate
100: power control device
110: power control unit
111: phase calculation unit
112: phase angle compensation unit
113: power amount setting unit
120: power measurement unit
200: thermal processing system
210: substrate support part
220: temperature measurement unit
221.222.223: temperature measurement sensor
230: heating intensity calculation unit
240: chamber
250: gas supply unit
260: exhaust unit
270: rotation support part
271: support ring
272: base plate

What is claimed is:

1. A power control device for temperature control, comprising:
a power control unit configured to control an amount of power supplied to a heating source by controlling a phase of AC power supplied from a power source; and
a power measurement unit connected to the power source and configured to measure the AC power,
wherein the power control unit controls the phase of the AC power by compensating a phase angle according to a difference between a reference power value and the measured value measured by the power measurement unit.

2. The power control device of claim 1, wherein the power control unit comprises:
a phase calculation unit configured to calculate a control phase for the AC power from the reference power value according to an amount of applied power to the heating source, and
a phase angle compensation unit configured to calculate the phase angle from a difference value between the reference power value and the measured value measured by the power measurement unit and compensate the phase angle for the control phase calculated by the phase calculation unit.

3. The power control device of claim 2, wherein the power control unit further comprises a power amount setting unit configured to set the amount of applied power according to an output of the heating source.

4. The power control device of claim 2, wherein the phase angle compensation unit is configured to calculate the phase angle in proportion to the difference value between the reference power value and the measured value measured by the power measurement unit.

5. The power control device of claim 4, wherein the phase angle compensation unit is configured to
add the phase angle to the control phase calculated by the phase calculation unit when the difference between the reference power value and the measured value measured by the power measurement unit is a positive number, and
subtract the phase angle from the control phase calculated by the phase calculation unit when the difference between the reference power value and the measured value measured by the power measurement unit is a negative number.

6. The power control device of claim 1, wherein the power source is configured to supply three-phase AC power.

7. The power control device of claim 6, wherein the power measurement unit is configured to measure AC power of each phase, and
the power control unit is configured to respectively control a phase of the AC power of each phase by respectively compensating the phase angle according to the difference between the reference power value and the measured value measured by the power measurement unit, for the AC power of each phase.

8. A thermal processing system comprising:
the power control device for temperature control according to claim 1;
a substrate support part provided opposite the heating source and configured to support a substrate;
a temperature measurement unit configured to measure a temperature of the substrate; and
a heating intensity calculation unit configured to calculate an output of the heating source according to the temperature of the substrate.

9. The thermal processing system of claim 8, wherein the heating source comprises a plurality of lamps.

10. The thermal processing system of claim 8, wherein an amount of applied power to the heating source is determined according to the output of the heating source calculated by the heating intensity calculation unit.

11. A temperature control method for a thermal processing system, comprising:
measuring a temperature of a substrate supported on a substrate support part;
calculating an output of a heating source that heats the substrate according to the measured temperature of the substrate;
setting an amount of applied power to the heating source according to the calculated output of the heating source; and
controlling an amount of power supplied to the heating source by controlling a phase of AC power supplied from a power source according to the set amount of applied power,
wherein the controlling the amount of power supplied to the heating source comprises:
a process of measuring the AC power, and
a process of controlling a phase of the AC power by compensating a phase angle according to a difference between the measured value of the AC power and a reference power value.

12. The temperature control method of claim 11, wherein the process of controlling the phase of the AC power comprises:
a process of calculating a control phase for the AC power from the reference power value according to the set amount of applied power,
a process of calculating the phase angle using a difference value between the reference power value and the measured value of the AC power, and
a process of compensating the calculated phase angle for the calculated control phase.

13. The temperature control method of claim 12, wherein
in the process of calculating the phase angle, the phase angle is calculated in proportion to the difference value between the measured value of the AC power and the reference power value.

14. The temperature control method of claim 13, wherein the process of compensating the calculated phase angle comprises:
a process of adding the calculated phase angle to the calculated control phase when a value obtained by subtracting the measured value of the AC power from the reference power value is a positive number, and
a process of subtracting the calculated phase angle from the calculated control phase when the value obtained by subtracting the measured value of the AC power from the reference power value is a negative number.

15. The temperature control method of claim 11, wherein the power source is configured to supply three-phase AC power, and
in the process of controlling the phase of the AC power, a phase of the AC power of each phase is respectively controlled by respectively compensating the phase angle according to the difference between the measured value of the AC power measured for the AC power of each phase and the reference power value.
